(19) United States
(12) Patent Application Publication
(10) Pub. No.: US 2026/0214889 A1
(43) Pub. Date: Jul. 23, 2026

(54) SEMICONDUCTOR DEVICE

(71) Applicant: SAMSUNG ELECTRONICS CO., LTD., Suwon-si (KR)

(72) Inventors: Hyunjae LEE, Suwon-si (KR); Seungmin LEE, Suwon-si (KR); Sungwon YOO, Suwon-si (KR)

(73) Assignee: SAMSUNG ELECTRONICS CO., LTD., Suwon-si (KR)

(21) Appl. No.: 19/404,272

(22) Filed: Dec. 1, 2025

(30) Foreign Application Priority Data
Jan. 17, 2025 (KR) 10-2025-0007555

(51) Int. Cl. H10B 12/00; H10D 30/01; H10D 30/67

(52) U.S. Cl. CPC H10B 12/488; H10B 12/33; H10B 12/482; H10B 12/485; H10D 30/6728; H10D 30/6735; H10D 30/6736; H10D 30/0312; H10D 30/0318

(57) ABSTRACT

A semiconductor device includes a first word line and a second word line spaced apart in a first horizontal direction and extending in a second horizontal direction, a first channel layer and a second channel layer on the inner sidewalls of the first word line and the second word line, a channel isolation insulating layer disposed between the first channel layer and the second channel layer, a bit line electrically connected to the first channel layer and the second channel layer, a first mold insulating layer facing an outer sidewall of each of the first word line and the second word line, and a second mold insulating layer disposed on the first mold insulating layer. The first mold insulating layer includes a recess, and the second mold insulating layer includes a portion extending into the recess of the first mold insulating layer.

### CROSS-REFERENCE TO RELATED APPLICATION

This application is based on and claims priority under 35 USC § 119 to Korean Patent Application No. 10-2025-0007555, filed on Jan. 17, 2025, in the Korean Intellectual Property Office, the disclosure of which is incorporated by reference herein in its entirety.

### BACKGROUND

The inventive concept relates to a semiconductor device, and more particularly, to a semiconductor device including vertical channel transistors.

As the design rules for semiconductor devices have been reduced, manufacturing technology has been developed toward an increase in the integration of semiconductor devices and improvement of an operating rate and yield. Accordingly, vertical channel transistors have been proposed to expand the integration, resistance, and current driving capabilities of transistors.

### SUMMARY

The inventive concept provides a semiconductor device including vertical channel transistors with improved electrical characteristics and device reliability.

However, the problems to be solved by the inventive concept are not limited to the problems mentioned above, and other problems may be clearly understood by those skilled in the art from the description below.

According to an aspect of the inventive concept, there is provided a semiconductor device including a first word line and a second word line spaced apart in a first horizontal direction and extending in a second horizontal direction intersecting the first horizontal direction, a gate insulating layer disposed on inner sidewalls of the first word line and the second word line, a first channel layer and a second channel layer respectively spaced apart from the inner sidewalls of the first word line and the second word line with the gate insulating layer therebetween, a channel isolation insulating layer disposed between the first channel layer and the second channel layer, a bit line contact plug disposed on the channel isolation insulating layer and electrically connected to the first channel layer and the second channel layer, a bit line disposed on the bit line contact plug, electrically connected to the bit line contact plug, and extending in the first horizontal direction, a first mold insulating layer facing an outer sidewall of each of the first word line and the second word line and extending in the second horizontal direction along the outer sidewall of each of the first word line and the second word line, and a second mold insulating layer disposed on the first mold insulating layer and covering opposite sidewalls and an upper surface of the bit line. The first mold insulating layer includes a recess, and the second mold insulating layer includes a portion extending into the recess of the first mold insulating layer.

According to another aspect of the inventive concept, there is provided a semiconductor device including a first word line and a second word line spaced apart in a first horizontal direction and extending in a second horizontal direction intersecting the first horizontal direction, a gate insulating layer disposed on inner sidewalls of the first word line and the second word line, a first channel layer and a second channel layer respectively spaced apart from the inner sidewalls of the first word line and the second word line with the gate insulating layer therebetween, a channel isolation insulating layer disposed between the first channel layer and the second channel layer, a bit line contact plug disposed on the channel isolation insulating layer and electrically connected to the first channel layer and the second channel layer, a bit line disposed on the bit line contact plug, electrically connected to the bit line contact plug, and extending in the first horizontal direction, a capping insulating layer covering outer sidewalls and upper surfaces of the first word line and the second word line and a portion of an outer sidewall and an upper surface of the gate insulating layer, and a mold insulating layer covering opposite sidewalls and an upper surface of the bit line and facing the outer sidewall of each of the first word line and the second word line. The mold insulating layer includes an air gap disposed in a position not overlapping the bit line in a vertical direction and not overlapping the first channel layer and the second channel layer in the first horizontal direction.

According to another aspect of the inventive concept, there is provided a semiconductor device including a first word line and a second word line spaced apart from each other in a first horizontal direction and extending in a second horizontal direction intersecting the first horizontal direction, a gate insulating layer disposed on inner sidewalls of the first word line and the second word line, a first channel layer and a second channel layer respectively spaced apart from the inner sidewalls of the first word line and the second word line with the gate insulating layer therebetween, a channel isolation insulating layer located between the first channel layer and the second channel layer, a bit line contact plug disposed on the channel isolation insulating layer and electrically connected to the first channel layer and the second channel layer, a bit line disposed on the bit line contact plug, electrically connected to the bit line contact plug, and extending in the first horizontal direction, a capping insulating layer covering outer sidewalls and upper surfaces of the first word line and the second word line and a portion of an outer sidewall and an upper surface of the gate insulating layer, a first mold insulating layer extending in the second horizontal direction on the capping insulating layer, and a second mold insulating layer disposed on the first mold insulating layer and covering opposite sidewalls and an upper surface of the bit line. The first mold insulating layer includes a recess, and the recess is disposed in a position not overlapping the bit line in a vertical direction and not overlapping the first channel layer and the second channel layer in the first horizontal direction.

### BRIEF DESCRIPTION OF THE DRAWINGS

Embodiments will be more clearly understood from the following detailed description taken in conjunction with the accompanying drawings in which:

FIG. 1 is a block diagram of a semiconductor device according to an embodiment;

FIG. 2 is a perspective view schematically illustrating a semiconductor device according to an embodiment;

FIG. 3 is a perspective view illustrating a semiconductor device according to an embodiment;

FIG. 4A is a cross-sectional view taken along line A1-A2 of FIG. 3;

FIG. 4B is a cross-sectional view taken along line B1-B2 of FIG. 3;

FIG. 4C is a cross-sectional view taken along line C1-C2 of FIG. 3;

FIG. 5 is a three-dimensional (3D) diagram illustrating a channel isolation insulating layer and bit line contact plug of FIG. 3;

FIG. 6 is a 3D diagram illustrating the channel isolation insulating layer and bit line sacrificial layer of FIG. 3;

FIGS. 7A and 7B are cross-sectional views illustrating a semiconductor device according to another embodiment;

FIGS. 8A, 8B, 9A, 9B, 10A, 10B, 10C, 11A, 11B, 11C, 12A, 12B, 12C, 13A, 13B, 13C, 14A, 14B, 15A, 15B, 16A, 16B, and 16C are cross-sectional views illustrating a method of manufacturing a semiconductor device, according to an embodiment, in which, FIGS. 8A, 9A, 10A, 11A, 12A, 13A, 14A, 15A, and 16A are perspective views illustrating a method of manufacturing a semiconductor device, according to an embodiment, FIGS. 8B, 9B, 10B, 11B, 12B, 13B, 14B, 15B, and 16B are cross-sectional views taken along line A1-A2 of FIG. 3, and FIGS. 10C, 11C, 12C, 13C, and FIG. 16C are cross-sectional views taken along line B1-B2 of FIG. 3;

FIG. 17 is a plan view of a memory module including a semiconductor device according to the inventive concept;

FIG. 18 is a schematic diagram of a memory card including a semiconductor device according to the inventive concept; and

FIG. 19 is a schematic diagram of a system including a semiconductor device according to the inventive concept.

### DETAILED DESCRIPTION OF THE EMBODIMENTS

Hereinafter, embodiments are described in detail with reference to the accompanying drawings. Like reference numerals denote like components in the drawings, and redundant descriptions thereof are omitted.

In this specification, the horizontal direction may include a first horizontal direction (an X direction) and a second horizontal direction (a Y direction) intersecting each other. A direction intersecting the first horizontal direction (the X direction) and the second horizontal direction (the Y direction) may be referred to as a vertical direction (a Z direction). Herein, a vertical level may be referred to as a height level in the vertical direction (the Z direction) of any component.

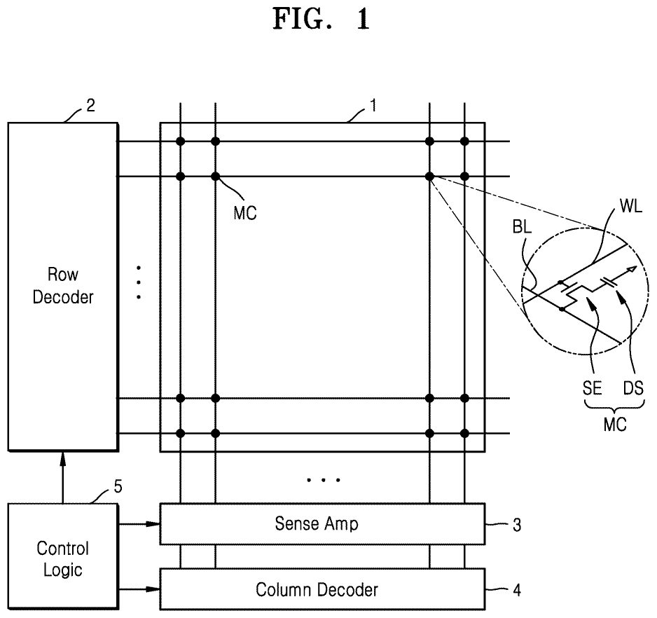

FIG. 1 is a block diagram of a semiconductor device according to an embodiment.

In some embodiments, the semiconductor device illustrated in FIG. 1 may be a memory device. In some embodiments, the semiconductor device illustrated in FIG. 1 may be a dynamic random access memory (DRAM) device. The semiconductor device may include a memory cell array 1, a row decoder 2, a sense amplifier 3, a column decoder 4, and control logic 5. The memory cell array 1 may include a plurality of memory cells MC arranged two-dimensionally or three-dimensionally.

Each of the plurality of memory cells MC may be connected between a word line WL and a bit line BL that intersect each other. Each of the plurality of memory cells MC may include a select element SE and a data storage element DS. The select element SE may be electrically connected in series to the data storage element DS.

The select element SE may be connected between the data storage element DS and the word line WL. The data storage element DS may be connected to the bit line BL through the select element SE. The select element SE may include a transistor.

The select element SE may include a vertical channel transistor (VCT). The select element SE may be a field effect transistor (FET). The data storage element DS may be implemented as a capacitor.

For example, a gate electrode of a transistor may be connected to the word line WL, and drain/source terminals of the transistor may be connected to the bit line BL and the data storage element DS, respectively.

The row decoder 2 may decode an address input from the outside and select one of a plurality of word lines WL of the memory cell array 1. The address decoded by the row decoder 2 may be provided to a row driver (not shown). The row driver may provide a voltage to each of the selected word line WL and a plurality of unselected word lines WL in response to a control signal of the control logic 5.

The sense amplifier 3 may detect and amplify a voltage difference between a selected bit line BL and a reference bit line according to a decoded address from the column decoder 4 and output the same. The column decoder 4 may provide a data transmission path between the sense amplifier 3 and an external device (e.g., a memory controller). The column decoder 4 may decode an address input from the outside and may select one of a plurality of bit lines BL. The control logic 5 may generate control signals for controlling operations for writing or reading data into or from the memory cell array 1.

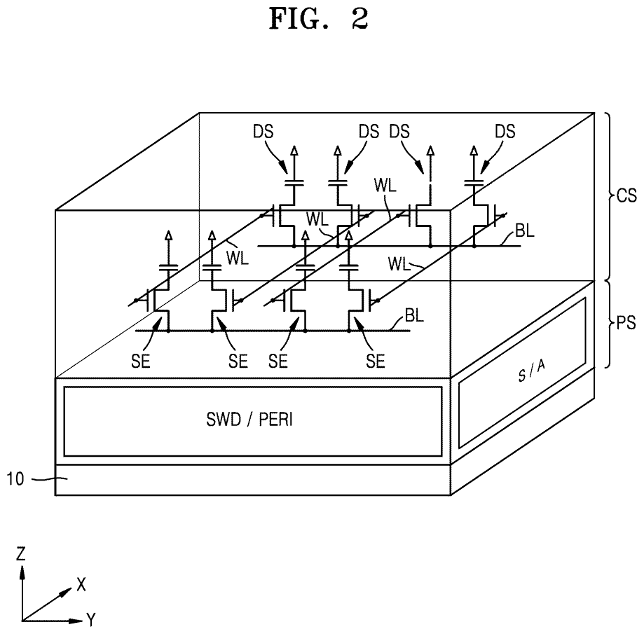

FIG. 2 is a perspective view schematically illustrating a semiconductor device according to an embodiment.

In an embodiment, the semiconductor device may include a peripheral circuit structure PS positioned on a substrate 10 and a cell array structure CS positioned on the peripheral circuit structure PS. The substrate 10 may be a peripheral circuit substrate. The peripheral circuit structure PS may include a core circuit and a peripheral circuit formed on the substrate 10. The peripheral circuit structure PS may include a core circuit and a peripheral circuit for operating the cell array structure CS.

The peripheral circuit structure PS may include peripheral circuits PERI including the row and column decoders (2 and 4 in FIG. 1) and the sense amplifier (3 in FIG. 1), and the control logic (5 in FIG. 1) described above and a source word line driver circuit SWD (3 in FIG. 1), and the control logics (5 in FIG. 1) described above. The peripheral circuit structure PS may be provided between the substrate 10 and the cell array structure CS in the vertical direction (the Z direction) perpendicular to an upper surface of the substrate 10.

The cell array structure CS may include a plurality of bit lines BL, a plurality of word lines WL, and a plurality of memory cells (MC in FIG. 1) positioned between the plurality of bit lines BL and the plurality of word lines WL. The plurality of memory cells (MC in FIG. 1) may be arranged two-dimensionally or three-dimensionally on a plane extending in the first horizontal direction (the X direction) and the second horizontal direction (the Y direction) that are parallel to upper surface of the substrate 10 and intersect each other.

Herein, a bit line direction may be the first horizontal direction (the X direction). A word line direction may be the second horizontal direction (the Y direction). A direction perpendicular to the substrate 10 may be the vertical direction. A direction perpendicular to the plane extending in the first horizontal direction (the X direction) and the second horizontal direction (the Y direction) may be the vertical direction (the Z direction).

Each of the plurality of memory cells (MC in FIG. 1) may include the select element SE and the data storage element DS, as described above. Each of the plurality of memory cells (MC in FIG. 1) may include the vertical channel transistor as the select element SE. The vertical channel transistor may refer to a structure in which a channel length extends in a direction perpendicular to the upper surface of the substrate 10 (the Z direction). The vertical channel transistor constituting the plurality of memory cells (MC in FIG. 1) may include a first channel layer and a second channel layer, a first gate insulating layer and a second gate insulating layer, and a first word line and a second word line, which are described below. Each of the plurality of memory cells (MC in FIG. 1) may include a capacitor as a plurality of data storage elements DS.

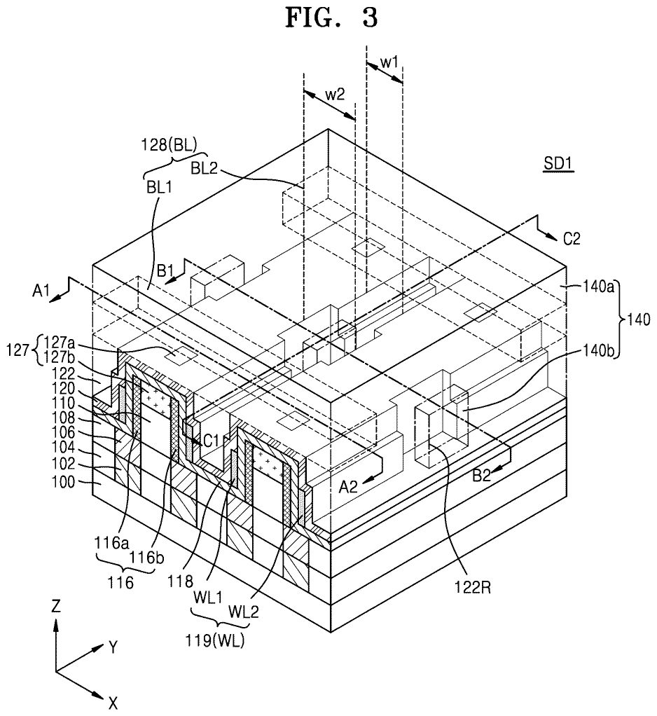

FIG. 3 is a perspective view illustrating a semiconductor device SD1 according to an embodiment.

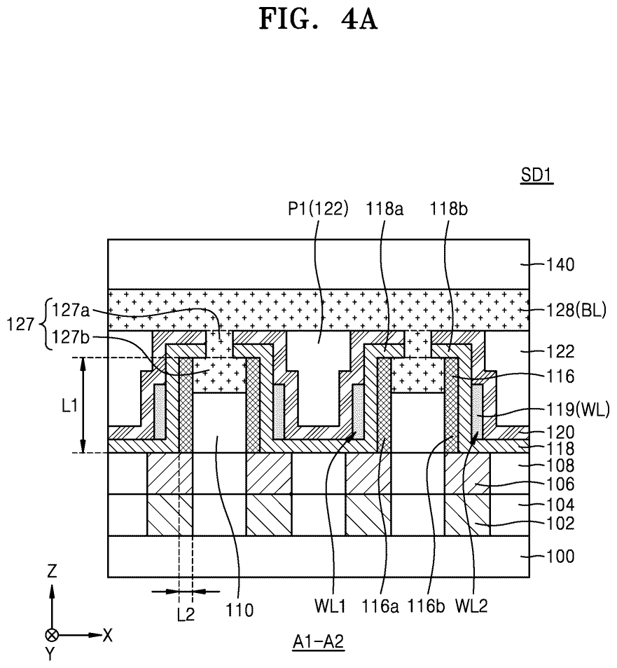

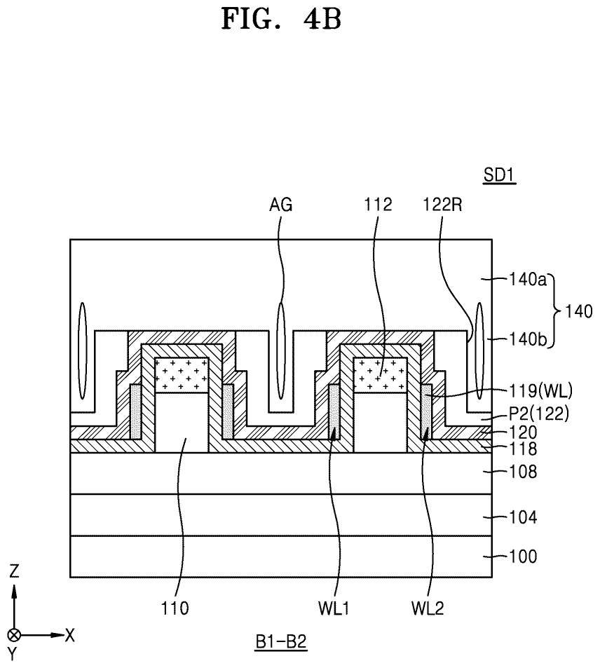

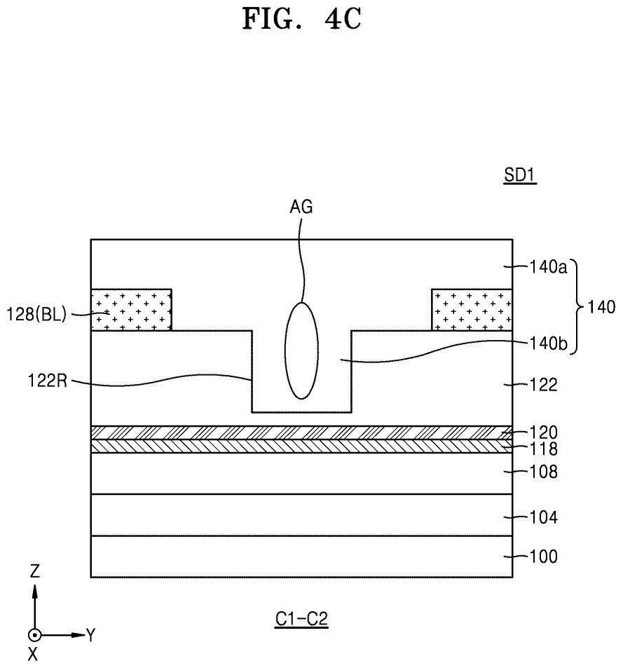

FIG. 4A is a cross-sectional view taken along line A1-A2 of FIG. 3.

FIG. 4B is a cross-sectional view taken along line B1-B2 of FIG. 3.

FIG. 4C is a cross-sectional view taken along line C1-C2 of FIG. 3.

A detailed configuration of the semiconductor device SD1 is described with reference to FIG. 3 and FIGS. 4A to 4C.

The semiconductor device SD1 is provided to describe the cell array structure (CS in FIG. 2). The cell array structure (CS in FIG. 2) may include a plurality of memory cells including vertical channel transistors.

In one or more embodiments, the semiconductor device SD1 may include a plurality of data storage elements 102, a plurality of landing pads 106, a channel isolation insulating layer 110, a plurality of channel layers 116, a gate insulating layer 118, a plurality of word lines 119, a capping insulating layer 120, a bit line contact plug 127, a plurality of bit lines 128, a first mold insulating layer 122, and a second mold insulating layer 140. The landing pad 106 may also be referred to as a buried contact BC.

The semiconductor device SD1 is shown as being formed on the substrate 100, but the substrate 100 may be removed for bonding with the peripheral circuit structure (PS of FIG. 2). The substrate 100 may be a carrier substrate. The substrate 100 may be a semiconductor substrate. The substrate 100 may be a silicon substrate, a germanium substrate, or a silicon-germanium substrate.

The semiconductor device SD1 may include the plurality of data storage elements 102 and a first interlayer insulating layer 104 arranged on the substrate 100. The plurality of data storage elements 102 may be apart from each other in the first horizontal direction (the X direction) and the second horizontal direction (the Y direction). Each of the plurality of data storage elements 102 may correspond to the data storage element DS or a portion of the data storage element DS of FIG. 2. The plurality of data storage elements 102 may be electrically connected to the plurality of channel layers 116 via the plurality of landing pads 106. The plurality of data storage elements 102 may be arranged below the plurality of channel layers 116. Each of the plurality of data storage elements 102 may include a capacitor.

The capacitor may include a lower electrode and an upper electrode, and a capacitor dielectric film located therebetween. The lower electrode and upper electrode may have various shapes, such as circular, oval, rectangular, square, rhombus, and hexagonal shapes, in a plan view. The plurality of memory cells described above may include the vertical channel transistor including the plurality of channel layers 116, the gate insulating layer 118, and the plurality of word lines WL and the data storage element 102.

The semiconductor device SD1 may include the plurality of landing pads 106 and the second interlayer insulating layer 108 respectively placed on the plurality of data storage elements 102 and the first interlayer insulating layer 104. The landing pads 106 may be apart from each other in the first horizontal direction (the X direction) and the second horizontal direction (the Y direction) from a planar perspective. The plurality of landing pads 106 may be arranged in various shapes, such as a matrix shape, a zigzag shape, a honeycomb shape, etc. In a plan view, each of the landing pads 106 may have various shapes, such as a circular, oval, rectangular, square, diamond, or hexagonal shape.

The first interlayer insulating layer 104 and the second interlayer insulating layer 108 may include at least one of silicon oxide, silicon nitride, and silicon oxynitride. The first interlayer insulating layer 104 and the second interlayer insulating layer 108 may include a single layer or multiple layers of the materials described above. In the present embodiment, the first interlayer insulating layer 104 may include silicon oxide, and the second interlayer insulating layer 108 may include silicon nitride. In the present embodiment, the first interlayer insulating layer 104 and the second interlayer insulating layer 108 may include silicon oxide.

The plurality of landing pads 106 may be arranged below the plurality of channel layers 116 and located between the plurality of channel layers 116 and the plurality of data storage elements 102. The plurality of landing pads 106 may be provided to electrically connect the plurality of data storage elements 102 to the plurality of channel layers 116. The plurality of landing pads 106 may include, but are not limited to, doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOₓ, RuOₓ, or combinations thereof.

The plurality of word lines 119 may correspond to the plurality of word lines WL of FIG. 2. The plurality of word lines 119 may be arranged apart from each other in the first horizontal direction (the X direction) on the substrate 100, may extend in the second horizontal direction (the Y direction), and may extend in the vertical direction (the Z direction) with respect to the substrate 100. The plurality of word lines 119 may be conductive patterns extending in the vertical direction (the Z direction) perpendicular to a plane along which the first horizontal direction (the X direction) and the second horizontal direction (the Y direction) extend. In some embodiments, a width of the plurality of word lines 119 may be from several nm to tens of nm.

The plurality of word lines 119 may include, but are not limited to, at least one of doped polysilicon, metals (e.g., Al, Cu, Ti, Ta, Ru, W, Mo, Pt, Ni, Co), conductive metal nitrides (e.g., TiN, TaN, WN, NbN, TiAlN, TiSiN, TaSiN, RuTiN), conductive metal silicides, and conductive metal oxides (e.g., PtO, RuO₂, IrO₂, SRO(SrRuO₃), BSRO((Ba, Sr)RuO₃), CRO(CaRuO₃), LSCo).

The plurality of word lines 119 may include a single layer or multiple layers of the materials described above. In some embodiments, the plurality of word lines 119 may include a two-dimensional (2D) semiconductor material. For example, the 2D semiconductor material may include graphene, carbon nanotubes, or combinations thereof.

The plurality of word lines 119 may include a first word line WL1 and a second word line WL2 that are adjacent to each other. The first word line WL1 may be positioned adjacent to the second word line WL2 in the first horizontal direction (the X direction). The first word line WL1 may be positioned to face the second word line WL2 in the first horizontal direction (the X direction).

The gate insulating layer 118 may extend higher than the first word line WL1 and the second word line WL2 in the vertical direction (the Z direction) on inner sidewalls of the first word line WL1 and the second word line WL2.

The gate insulating layer 118 may extend on outer sidewalls of a first channel layer 116a and a second channel layer 116b and the channel isolation insulating layer 110. As illustrated in FIG. 4A, the gate insulating layer 118 may cover the outer sidewalls of the first channel layer 116a and the second channel layer 116b, upper surfaces of the first channel layer 116a and the second channel layer 116b, and a portion of an upper surface of the bit line contact plug 127. For example, the gate insulating layer 118 may cover an upper surface of the second bit line contact plug 127b of the bit line contact plugs 127. As illustrated in FIG. 4B, the gate insulating layer 118 may cover portions of the opposite sidewalls of the channel isolation insulating layer 110 and a sidewall and upper surface of a bit line sacrificial layer 112. Because the plurality of channel layers 116 are arranged apart from each other in the second horizontal direction (the Y direction), portions of the opposite sidewalls of the channel isolation insulating layer 110 may be exposed and not covered by the plurality of channel layers 116, but the other portions may be covered by the plurality of channel layers 116.

The gate insulating layer 118 may be located between the plurality of word lines WL and the plurality of channel layers 116 to isolate the plurality of word lines WL from the plurality of channel layers 116. The gate insulating layer 118 may be located between the first word line WL1 and the first channel layer 116a and between the second word line WL2 and the second channel layer 116b. A portion of the gate insulating layer 118 located between the first word line WL1 and the first channel layer 116a may be referred to as a first gate insulating layer 118a, and a portion of the gate insulating layer 118 located between the second word line WL2 and the second channel layer 116b may be referred to as a second gate insulating layer 118b. In some embodiments, the gate insulating layer 118 may have a thickness of several nm.

The gate insulating layer 118 may include at least one of silicon oxide, silicon oxynitride, and a high-k material having a dielectric constant higher than that of silicon oxide. The high-k material may include metal oxide or metal oxynitride. For example, high-k materials usable as the gate insulating layer 118 may include, but are not limited to, at least one of HfO₂, HfSiO, HfSiON, HfTaO, HfTiO, HfZrO, ZrO₂, and Al₂O₃.

The plurality of channel layers 116 may extend in the vertical direction (the Z direction) on the inner sidewall of the gate insulating layer 118. The plurality of channel layers 116 may be arranged apart in the first horizontal direction (the X direction) and the second horizontal direction (the Y direction). The plurality of channel layers 116 may face the inner sidewalls of each of the first word line WL1 and the second word line WL2 and may extend vertically along the inner sidewall of each of the first word line WL1 and the second word line WL2.

The plurality of channel layers 116 may include source and drain regions above and below the plurality of word lines 119 in the vertical direction (the Z direction). In some embodiments, thicknesses of the plurality of channel layers 116 may be several nm. The plurality of channel layers 116 may include the first channel layer 116a and the second channel layer 116b. The first channel layer 116a and the second channel layer 116b may be apart from the inner sidewalls of the first word line WL1 and the second word line WL2, respectively, with the first gate insulating layer 118a and the second gate insulating layer 118b therebetween. Vertical levels of upper surfaces of the first channel layer 116a and the second channel layer 116b may be higher than vertical levels of the upper surfaces of the first word line WL1 and the second word line WL2 in the vertical direction (the Z direction).

As illustrated in FIG. 4A, a length L2 of the first channel layer 116a and the second channel layer 116b in the first horizontal direction (the X direction) may be less than a length L1 of the first channel layer 116a and the second channel layer 116b in the vertical direction (the Z direction). The first channel layer 116a and the second channel layer 116b may include a first contact portion CT1 in contact with the second bit line contact plug 127b and a second contact portion CT2 in contact with the channel isolation insulating layer 110.

The second bit line contact plug 127b in contact with the first contact portion CT1 of each of the first channel layer 116a and the second channel layer 116b is formed by filling a second contact hole 126 with a conductive material, and thus, a contact length in the vertical direction (the Z direction) between the first contact portion CT1 of each of the first channel layer 116a and the second channel layer 116b and the second bit line contact plug 127b may be easily adjusted.

The plurality of channel layers 116 may be named a semiconductor pattern. The plurality of channel layers 116 may include oxide semiconductor. The oxide semiconductor may include at least one of, but is not limited to, InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, and InₓGa_{y}O.

In some embodiments, the plurality of channel layers 116 may include indium gallium zinc oxide (IGZO). The plurality of channel layers 116 may include a single layer or multiple layers of oxide semiconductor. The plurality of channel layers 116 may include an amorphous, crystalline, or polycrystalline oxide semiconductor.

In some embodiments, the plurality of channel layers 116 may have a bandgap energy greater than a bandgap energy of silicon. The plurality of channel layers 116 may have a band gap energy of about 1.5 eV to 5.6 eV. The plurality of channel layers 116 may have optimal channel performance when they have a band gap energy of about 2.0 eV to 4.0 eV. The plurality of channel layers 116 may include a 2D semiconductor material. For example, the 2D semiconductor material may include graphene, carbon nanotubes, or combinations thereof.

The channel isolation insulating layer 110 may be located between the first channel layer 116a and the second channel layer 116b and may extend in the second horizontal direction (the Y direction). The channel isolation insulating layer 110 may separate and insulate the first channel layer 116a from the second channel layer 116b. The channel isolation insulating layer 110 may be formed at a height lower than that of the upper surfaces of the first channel layer 116a and the second channel layer 116b.

The channel isolation insulating layer 110 may include at least one of silicon oxide, silicon nitride, and silicon oxynitride. The channel isolation insulating layer 110 may include a single layer or multiple layers of the material described above. In the present embodiment, the channel isolation insulating layer 110 may include silicon oxide.

The bit line contact plug 127 may be placed on the channel isolation insulating layer 110. At least a portion of the bit line contact plug 127 is in contact with the first channel layer 116a and the second channel layer 116b in the first horizontal direction (the X direction), and thus may be in contact with both the first channel layer 116a and the second channel layer 116b. In other words, the bit line contact plug 127 may electrically connect one bit line 128 to two channel layers (116, for example, the first channel layer 116a and the second channel layer 116b). The bit line contact plug 127 may include a first bit line contact plug 127a and the second bit line contact plug 127b.

The bit line sacrificial layer 112 may be placed on the channel isolation insulating layer 110. The bit line sacrificial layer 112 may be in contact with the gate insulating layer 118 in the first horizontal direction (the X direction). The bit line sacrificial layer 112 may include an insulating material.

In some embodiments, the semiconductor device SD1 may further include a capping insulating layer 120 covering the upper surface and outer sidewalls of the first word line WL1 and the second word line WL2, portions of the outer sidewalls of the gate insulating layer 118 that are not covered by the first word line WL1 and the second word line WL2, and the upper surface of the gate insulating layer 118. In some embodiments, a thickness of the capping insulating layer 120 may be several nm.

The capping insulating layer 120 may include at least one of silicon oxide, silicon nitride, and silicon oxynitride. The capping insulating layer 120 may include a single layer or multiple layers of the material described above. In the present embodiment, the capping insulating layer 120 may include silicon nitride.

The first bit line contact plug 127a may be placed within a first contact hole penetrating the capping insulating layer 120 and the gate insulating layer 118 positioned on the first bit line contact plug 127a. The second bit line contact plug 127b may be placed in a second contact hole that contacts the first channel layer 116a and the second channel layer 116b on the channel isolation insulating layer 110.

The first mold insulating layer 122 may face the outer sidewall of each of the first word line WL1 and the second word line WL2 and may extend in the second horizontal direction (the Y direction) along the outer wall of each of the first word line WL1 and the second word line WL2.

The first mold insulating layer 122 may include a recess 122R. The second mold insulating layer 140 may include a portion extending into the recess 122R. The recess 122R may be positioned at a position that does not overlap the plurality of channel layers 116 in the first horizontal direction (the X direction). The recess 122R may be placed at a position that does not overlap the bit line 128 in the vertical direction (the Z direction). The first mold insulating layer 122 may be exposed from a bottom surface and side surface of the recess 122R, and the capping insulating layer 120 may be apart from the bottom surface and side surface of the recess 122R.

The first mold insulating layer 122 may include a first portion P1 that overlaps the first channel layer 116a and the second channel layer 116b in the first horizontal direction (the X direction) and a second portion P2 that does not overlap the first channel layer 116a and the second channel layer 116b in the first horizontal direction (the X direction). The recess 122R may be placed in the second portion P2. The first portion P1 of the first mold insulating layer 122 may have a first width w1 in the first horizontal direction (the X direction), and the second portion P2 may have a second width w2 in the first horizontal direction (the X direction). The second width w2 of the second portion P2 may be greater than the first width w1 of the first portion P1. A difference between the first width w1 of the first portion P1 and the second width w2 of the second portion P2 may be equal to a width of the first channel layer 116a and the second channel layer 116b in the first horizontal direction (the X direction).

The second mold insulating layer 140 may be placed on the first mold insulating layer 122, may cover the opposite sidewalls and upper surfaces of the plurality of bit lines 128, and may extend in the first horizontal direction (the X direction) and the second horizontal direction (the Y direction) along the opposite sidewalls and upper surface of each of the plurality of bit lines 128.

The second mold insulating layer 140 may include a main extension 140a covering the opposite sidewalls and the upper surface of each of the plurality of bit lines 128 and a sub-extension 140b extending from the main extension 140a into the recess 122R. The sub-extension 140b may not overlap the first channel layer 116a and the second channel layer 116b in the first horizontal direction (the X direction). The sub-extension 140b may include an air gap AG. As used herein, “air gap” may be understood as including any cavity substantially filled with inert gas or gaseous material, including, but not limited to, air or other gases which may be present during a manufacturing process or as including a gap of which the interior is formed by a vacuum and free of solid material. The air gap AG may extend from inside the sub-extension 140b to inside the main extension 140a, and the main extension 140a and the sub-extension 140b may surround the air gap AG.

The first mold insulating layer 122 and the second mold insulating layer 140 may include at least one of silicon oxide, silicon nitride, and silicon oxynitride. The first mold insulating layer 122 and the second mold insulating layer 140 may include a single layer or multiple layers. The first mold insulating layer 122 and the second mold insulating layer 140 may include different materials.

In one or more embodiments, the air gap AG may be located between a pair of word lines 119 that are adjacent to each other in the first horizontal direction (the X direction) and connected to different bit lines BL among the plurality of word lines 119. In addition, the air gap AG may be located between the plurality of bit lines 128.

According to embodiments, because the air gap AG having a relatively low permeability is located between the plurality of word lines 119 and between the plurality of bit lines 128, parasitic capacitance between the plurality of word lines 119 and between the plurality of bit lines 128 may be relatively reduced.

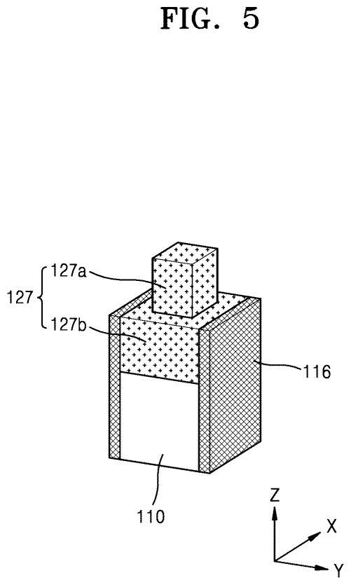

FIG. 5 is a 3D diagram illustrating the channel isolation insulating layer 110 and the bit line contact plug 127 of FIG. 3.

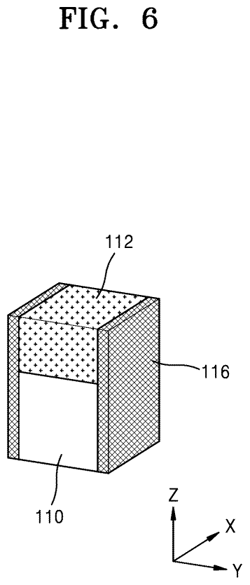

FIG. 6 is a 3D diagram illustrating the channel isolation insulating layer 110 and the bit line sacrificial layer 112 of FIG. 3.

In detail, in FIGS. 5 and 6, the same reference numerals as those in FIGS. 3 to 4A, 4B, and 4C denote the same members.

As illustrated in FIG. 5, the channel isolation insulating layer 110 may be positioned between the plurality of channel layers 116. The bit line contact plug 127 may be positioned on the channel isolation insulating layer 110.

The bit line contact plug 127 may include the first bit line contact plug 127a and the second bit line contact plug 127b. The first bit line contact plug 127a may have a smaller capacity (volume) than the second bit line contact plug 127b.

As illustrated in FIG. 6, the channel isolation insulating layer 110 may be positioned between the plurality of channel layers 116. The bit line sacrificial layer 112 may be positioned on the channel isolation insulating layer 110. The bit line sacrificial layer 112 may be an insulating layer. In a region in which the bit line contact plug 127 is not formed in the semiconductor device SD1, the bit line sacrificial layer 112 may be formed to prevent electrical connection between the plurality of channel layers 116 and the plurality of bit lines 128.

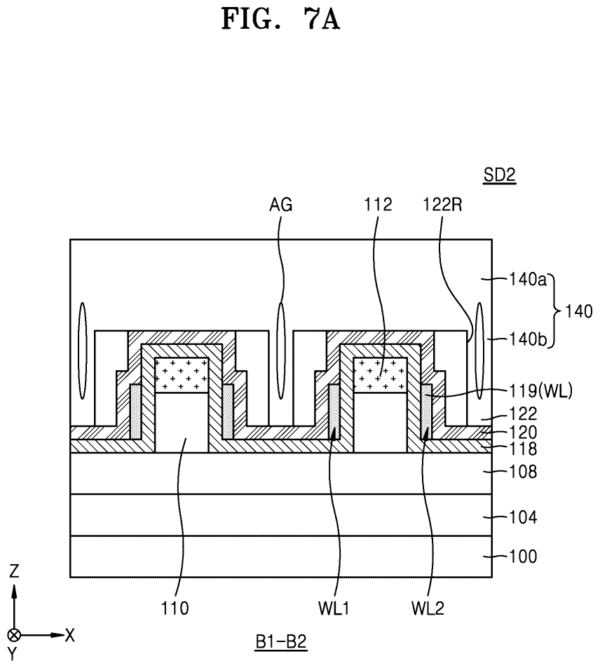

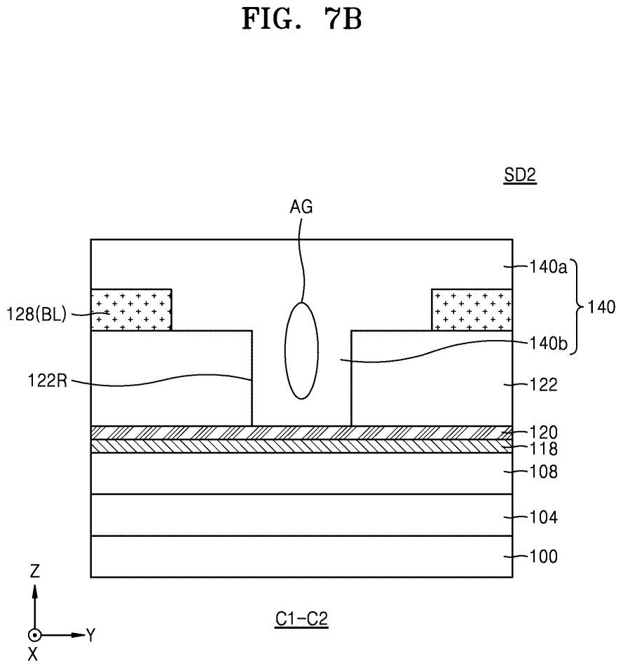

FIGS. 7A and 7B are cross-sectional views illustrating a semiconductor device SD2 according to another embodiment. Because the semiconductor device SD2 is configured similarly to the semiconductor device SD1 described above, the differences from the semiconductor device SD1 are mainly described below.

Referring to FIGS. 7A and 7B, the semiconductor device SD2 may include the plurality of data storage elements 102, the plurality of landing pads 106, the channel isolation insulating layer 110, the plurality of channel layers 116, the gate insulating layer 118, the plurality of word lines 119, the capping insulating layer 120, the bit line contact plug 127, the plurality of bit lines 128, the first mold insulating layer 122, and the second mold insulating layer 140. The landing pad 106 may also be referred to as a buried contact BC.

The first mold insulating layer 122 may include the recess 122R. The second mold insulating layer 140 may include a portion extending into the recess 122R. The capping insulating layer 120 may be exposed from the bottom surface of the recess 122R, and the first mold insulating layer 122 may be exposed from a side surface of the recess 122R. The capping insulating layer 120 may be apart from the side surface of the recess 122R.

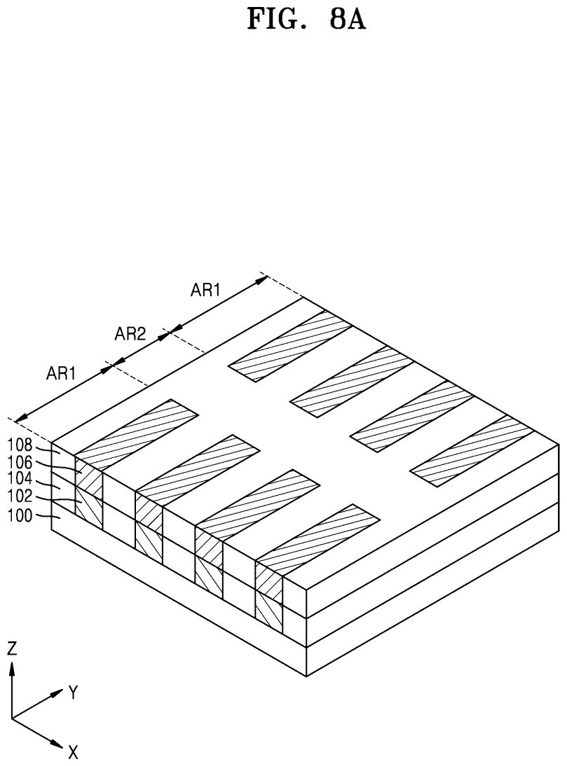

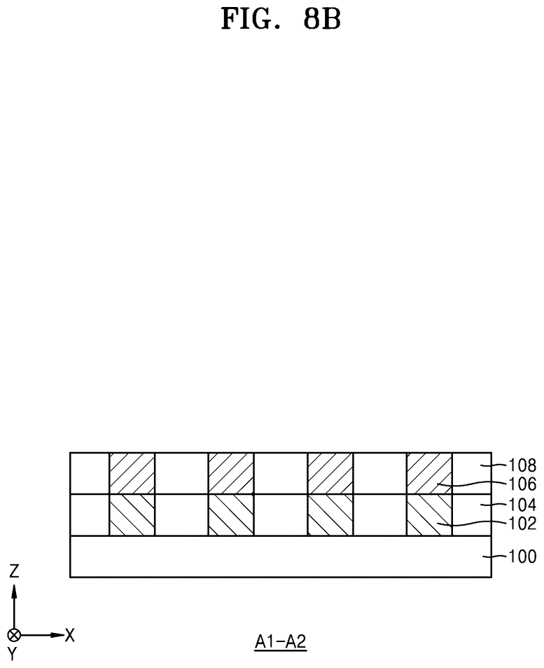

FIGS. 8A, 8B, 9A, 9B, 10A, 10B, 10C, 11A, 11B, 11C, 12A, 12B, 12C, 13A, 13B, 13C, 14A, 14B, 15A, 15B, 16A, 16B, and 16C are cross-sectional views illustrating a method of manufacturing a semiconductor device, according to an embodiment.

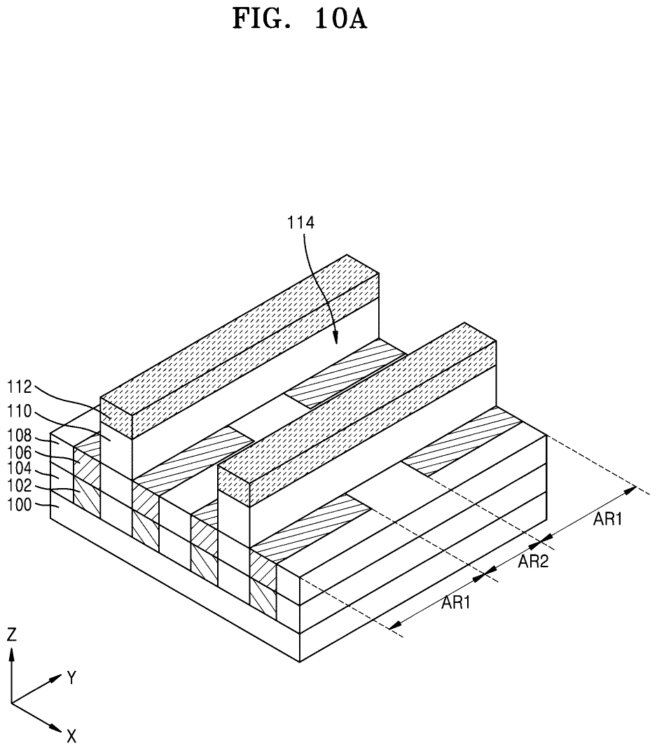

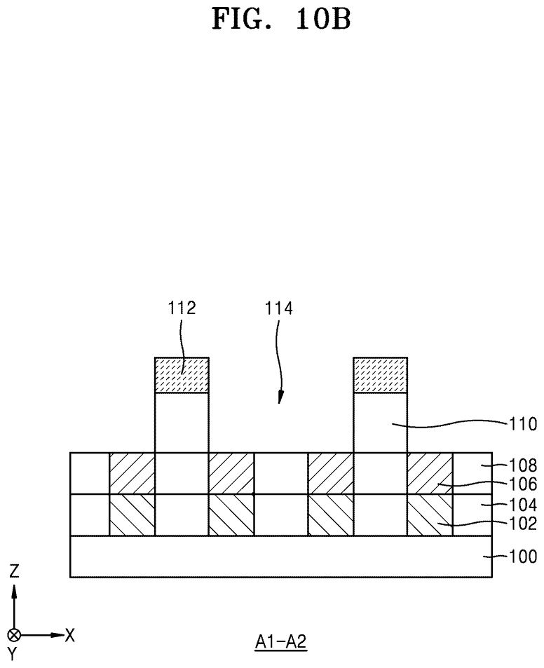

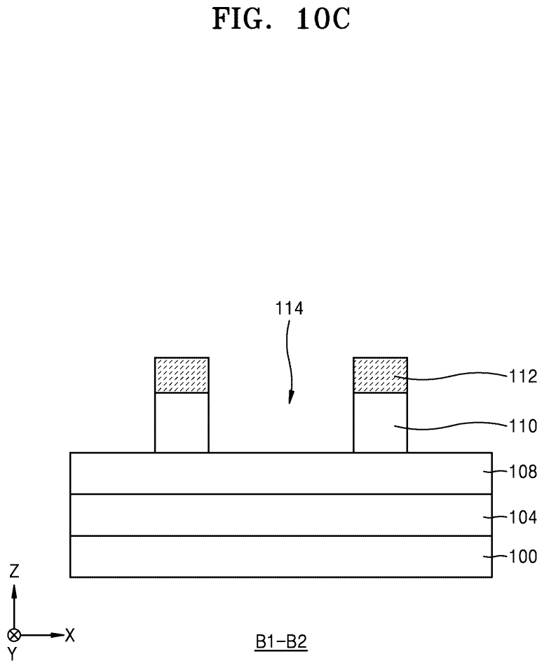

In detail, FIGS. 8A, 9A, 10A, 11A, 12A, 13A, 14A, 15A, and 16A are perspective views illustrating a method of manufacturing a semiconductor device, according to an embodiment, FIGS. 8B, 9B, 10B, 11B, 12B, 13B, 14B, 15B, and 16B are cross-sectional views corresponding to the cross-sections taken along line A1-A2 of FIG. 3, and FIGS. 10C, 11C, 12C, 13C, and FIG. 16C are cross-sectional views corresponding to the cross-sections taken along line B1-B2 of FIG. 3.

Referring to FIGS. 8A and 8B, the plurality of data storage elements 102 and the first interlayer insulating layer 104 are formed on the substrate 100 including a first region AR1 and a second region AR2. The substrate 100 may be a semiconductor substrate. The substrate 100 may be a silicon substrate, a germanium substrate, or a silicon-germanium substrate.

The first interlayer insulating layer 104 may insulate the plurality of data storage elements 102. The plurality of data storage elements 102 may correspond to the plurality of data storage elements DS of FIG. 2. The plurality of data storage elements 102 may be implemented as capacitors.

The plurality of landing pads 106 and the second interlayer insulating layer 108 are formed on the plurality of data storage elements 102 and the first interlayer insulating layer 104. The second interlayer insulating layer 108 may insulate the plurality of landing pads 106.

The plurality of data storage elements 102 and the plurality of landing pads 106 may be formed in the first region AR1, and the first interlayer insulating layer 104 and the second interlayer insulating layer 108 may fill a space between the plurality of data storage elements 102 and a space between the plurality of landing pads 106 in the first region AR1 and the second region AR2.

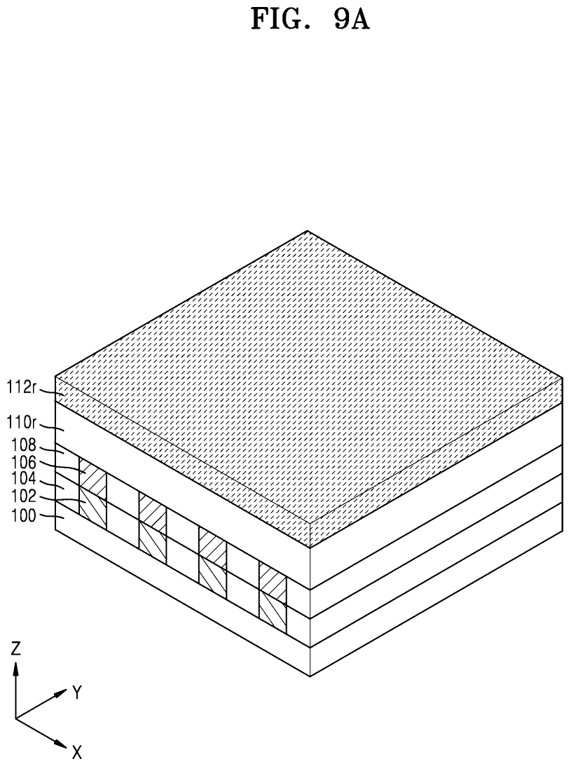

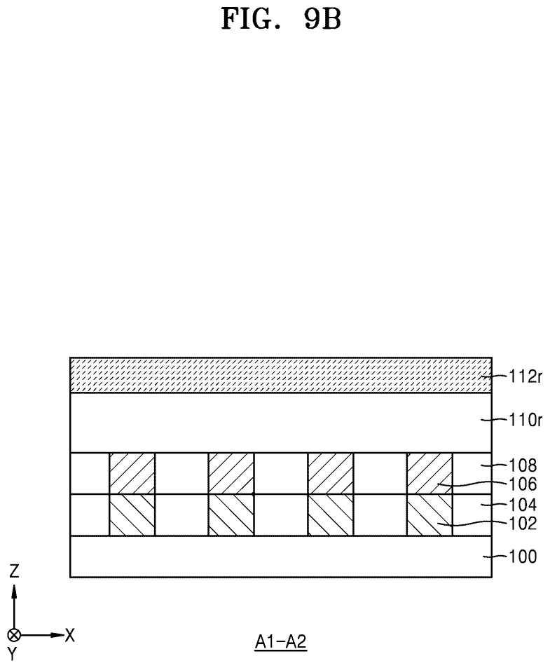

Referring to FIGS. 9A and 9B, a channel isolation insulating material layer 110r is formed on the plurality of landing pads 106 and the second interlayer insulating layer 108. The channel isolation insulating material layer 110r may be a mold insulating material layer. The channel isolation insulating material layer 110r may include at least one of silicon oxide, silicon nitride, and silicon oxynitride.

The channel isolation insulating material layer 110r may include a single layer or multiple layers of the material described above. In the present embodiment, the channel isolation insulating material layer 110r may include silicon oxide.

A bit line sacrificial material layer 112r is formed on the channel isolation insulating material layer 110r. The bit line sacrificial material layer 112r may include at least one of silicon oxide, silicon nitride, and silicon oxynitride. The bit line sacrificial material layer 112r may include a single layer or multiple layers of the material described above. In the present embodiment, the bit line sacrificial material layer 112r may include silicon nitride.

Referring to FIGS. 10A, 10B, and 10C, the bit line sacrificial material layer 112r and the channel isolation insulating material layer 110r are patterned to form the bit line sacrificial layer 112 and the channel isolation insulating layer 110. The bit line sacrificial material layer 112r and the channel isolation insulating material layer 110r may be patterned using a photolithography process.

According to the patterning of the bit line sacrificial material layer 112r and the channel isolation insulating material layer 110r, a mold trench 114 exposing the plurality of landing pads 106 and the second interlayer insulating layer 108 may be formed inside the bit line sacrificial layer 112 and the channel isolation insulating layer 110. In other words, the bit line sacrificial layer 112 and the channel isolation insulating layer 110 may have the mold trench 114 exposing the plurality of landing pads 106 and the second interlayer insulating layer 108.

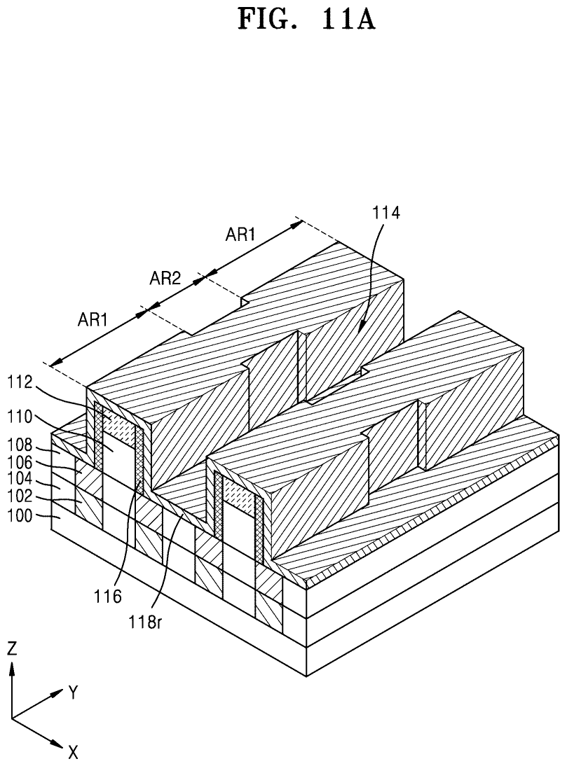

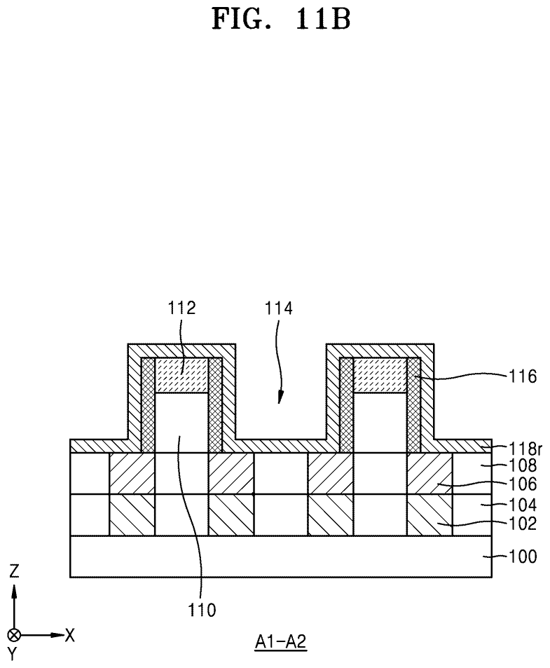

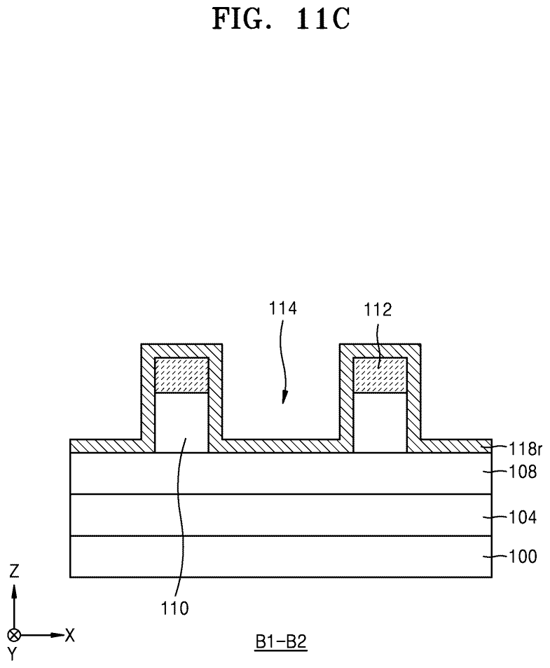

Referring to FIGS. 11A, 11B, and 11C, the plurality of channel layers 116 are formed on an inner sidewall of the mold trench 114. The plurality of channel layers 116 may be formed on one sidewall of the bit line sacrificial layer 112 and the channel isolation insulating layer 110. The plurality of channel layers 116 may be formed on the opposite sidewalls of the bit line sacrificial layer 112 and the channel isolation insulating layer 110 facing each other. The plurality of channel layers 116 may include the first channel layer 116a and the second channel layer 116b facing each other.

The plurality of channel layers 116 may be formed by forming a channel material layer on a resultant structure in which the mold trench 114 is formed as shown in FIGS. 10A, 10B, and 10C and then patterning the channel material layer by using a photolithography process. The plurality of channel layers 116 may be semiconductor patterns including oxide semiconductor. The plurality of channel layers 116 may be placed in the first region AR1 among the first region AR1 and the second region AR2.

A gate insulating material layer 118r is formed on the bit line sacrificial layer 112, the plurality of channel layers 116, and the mold trench 114. In the first region AR1, the gate insulating material layer 118r may be formed on the bottom of the mold trench 114, the sidewalls and upper surfaces of the plurality of channel layers 116, the upper surface of the bit line sacrificial layer 112, and the upper surfaces of the plurality of landing pads 106 and the second interlayer insulating layer 108. On the second region AR2, the gate insulating material layer 118r may be formed on the bottom of the mold trench 114, the sidewall of the channel isolation insulating layer 110, the sidewall and upper surface of the bit line sacrificial layer 112, and the upper surfaces of the plurality of landing pads 106 and the second interlayer insulating layer 108.

The gate insulating material layer 118r may include a material including at least one of silicon oxide, silicon oxynitride, and a high-k material having a dielectric constant higher than that of silicon oxide.

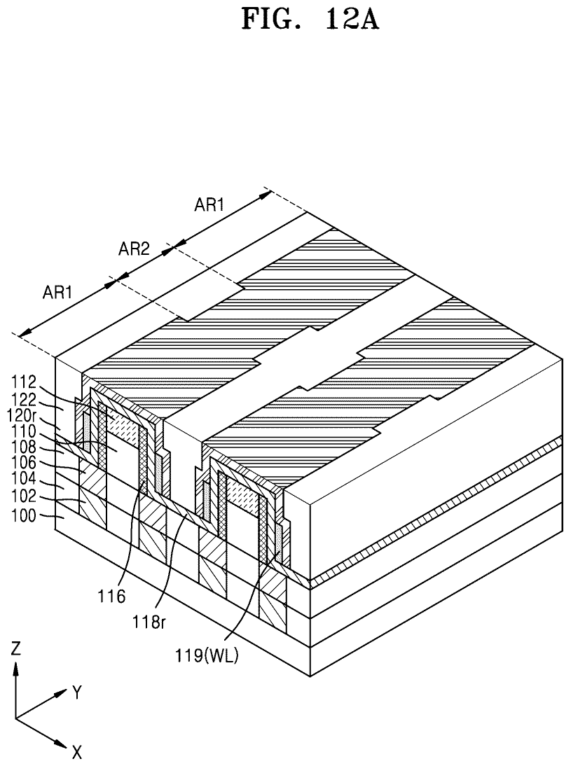

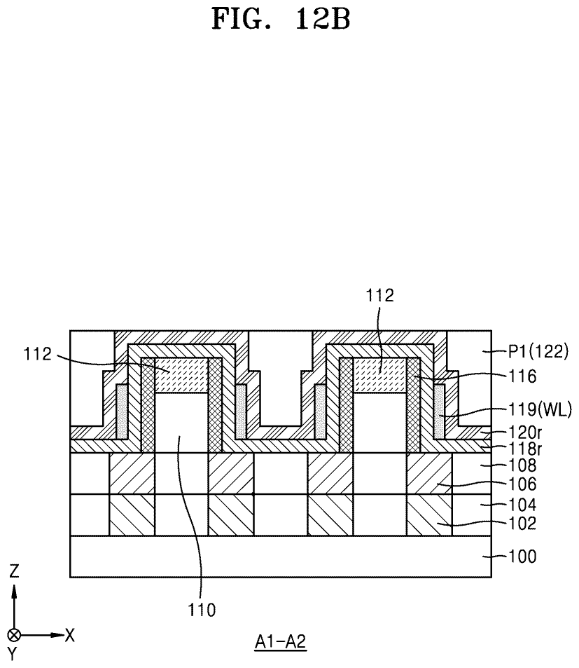

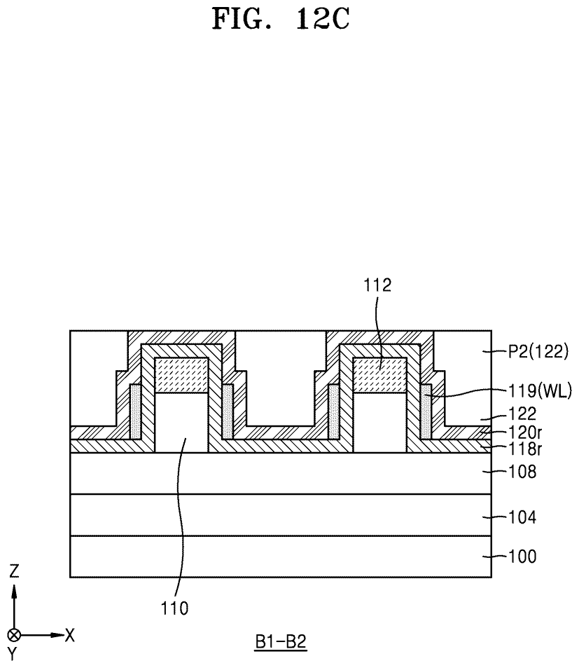

Referring to FIGS. 12A, 12B, and 12C, the plurality of word lines 119 are formed on one sidewall of the gate insulating material layer 118r within the mold trench (114 of FIGS. 11A, 11B, and 11C). The plurality of word lines 119 may be formed apart from each other in the first horizontal direction (the X direction). The plurality of word lines 119 may be formed at a height lower than those of the upper surfaces of the plurality of channel layers 116. The plurality of word lines 119 may extend in the vertical direction (the Z direction) on the gate insulating material layer 118r. The plurality of word lines 119 may be formed on the outer sidewalls of the plurality of channel layers 116.

The plurality of word lines 119 may include the first word line WL1 and the second word line WL2 that are adjacent to each other. The first word line WL1 may be positioned adjacent to the second word line WL2 in the first horizontal direction (the X direction).

The first word line WL1 and the second word line WL2 may be formed with the gate insulating material layer 118r therebetween on the outer sidewalls of the first channel layer 116a and the second channel layer 116b, respectively. The gate insulating material layer 118r may include the first gate insulating layer 118a formed on one sidewall of the first channel layer 116a and the second gate insulating layer 118b formed on one sidewall of the second channel layer 116b.

A capping insulating material layer 120r is formed on the gate insulating material layer 118r and the plurality of word lines 119 within the mold trench (114 in FIGS. 11A, 11B, and 11C). The capping insulating material layer 120r may be formed on the upper surface of the gate insulating material layer 118r and the upper surface and one sidewall of the plurality of word lines 119,. The capping insulating material layer 120r may include at least one of silicon oxide, silicon nitride, and silicon oxynitride. The capping insulating material layer 120r may include a single layer or multiple layers of the material described above. In the present embodiment, the capping insulating material layer 120r may include silicon nitride.

Subsequently, the first mold insulating layer 122 is formed to fill the inside of the mold trench (114 in FIGS. 11A, 11B, and 11C) on the capping insulating material layer 120r. The first mold insulating layer 122 may be formed by forming an insulating material layer on the capping insulating material layer 120r to fill the inside of the mold trench (114 in FIGS. 11A, 11B, and 11C) and then performing a planarization process.

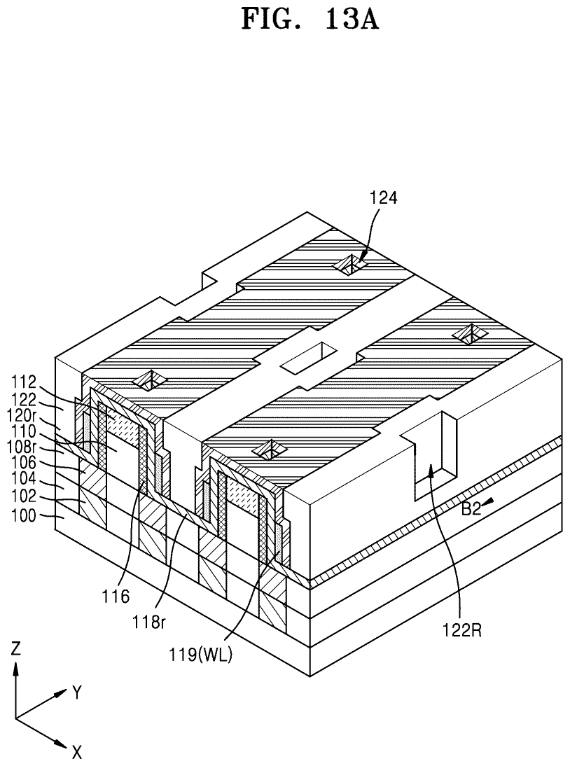

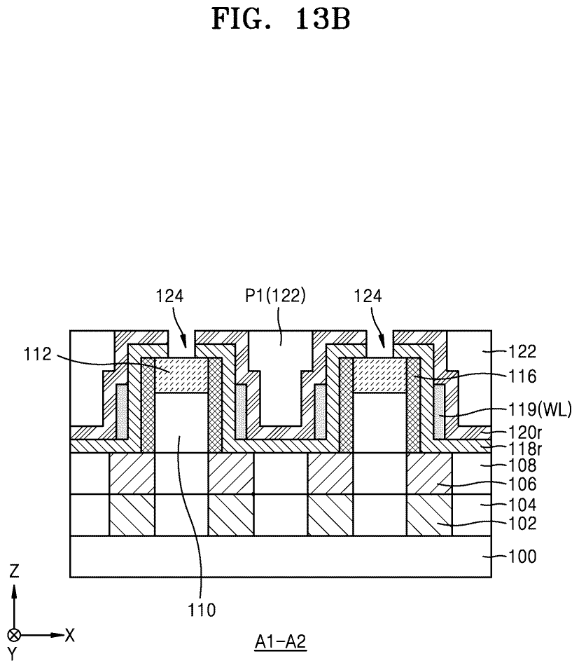

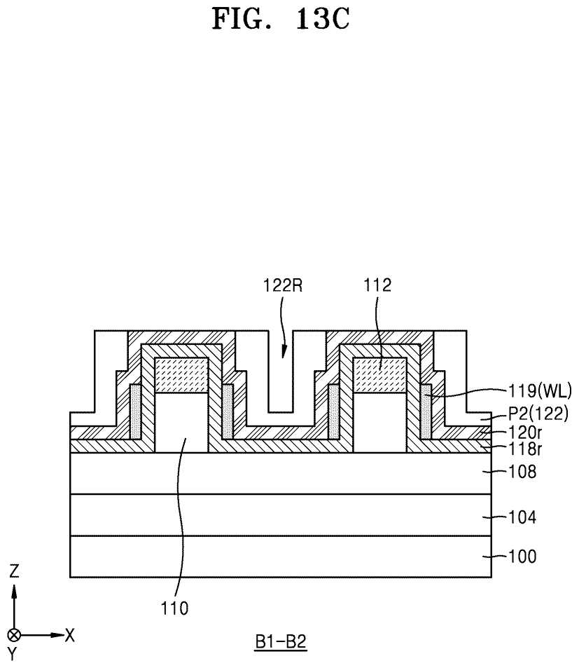

Referring to FIGS. 13A, 13B, and 13C, the capping insulating material layer 120r and the gate insulating material layer 118r on the bit line sacrificial layer 112 are patterned to form a first contact hole 124 in the first region AR1. The first contact hole 124 may expose the upper surface of the bit line sacrificial layer 112. The first contact hole 124 may be formed by patterning the capping insulating material layer 120r and the gate insulating material layer 118r by using a photolithography process.

According to the patterning of the capping insulating material layer 120r and the gate insulating material layer 118r, the capping insulating material layer 120r and the gate insulating material layer 118r may become the capping insulating layer 120 and the gate insulating layer 118, respectively. The gate insulating layer 118 may include the first gate insulating layer 118a and the second gate insulating layer 118b formed on one sidewalls of the first word line WL1 and the second word line WL2, respectively.

In addition, the first mold insulating layer 122 is patterned to form the recess 122R in the second region AR2. The recess 122R may be formed by etching a portion of the first mold insulating layer 122R, and the first mold insulating layer 122R may be exposed from the side and bottom surfaces of the recess 122R. In some other embodiments, the first mold insulating layer 122R may be exposed from the side surface of the recess 122R, and the capping insulating layer 120 may be exposed from the bottom surface of the recess 122R.

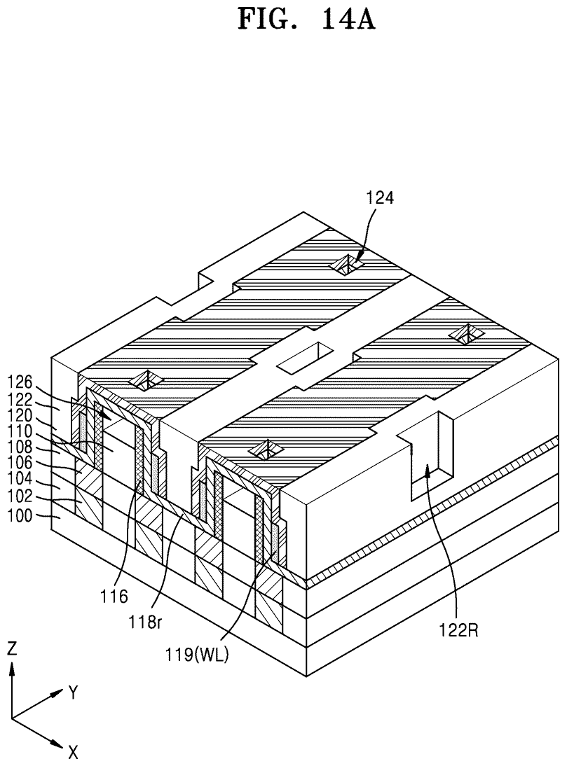

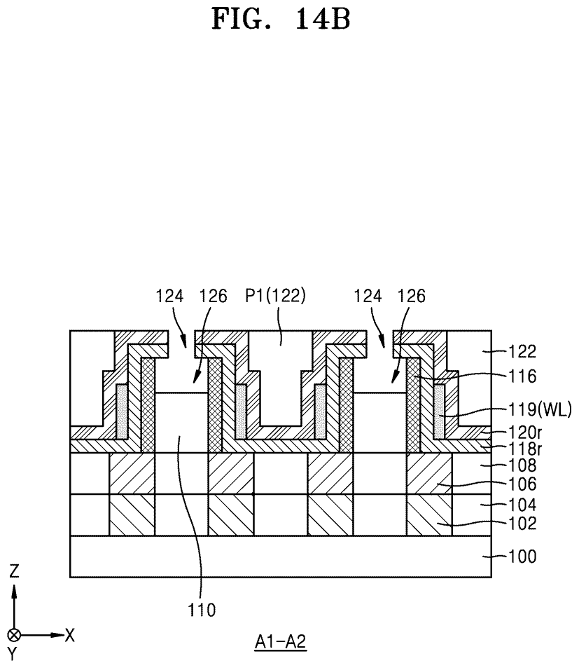

Referring to FIGS. 14A and 14B, the bit line sacrificial layer 112 exposed by the first contact hole 124 is etched to form the second contact hole 126. The first contact hole 124 may communicate with the second contact hole 126.

The second contact hole 126 may have a greater width (or diameter) than that of the first contact hole 124. As the second contact hole 126 is formed, the upper surface of the channel isolation insulating layer 110 and internal surfaces of the first channel layer 116a and the second channel layer 116b may be exposed. In the second region AR2 in which the bit line contact plug 127 is not formed, the bit line sacrificial layer 112 may not be etched.

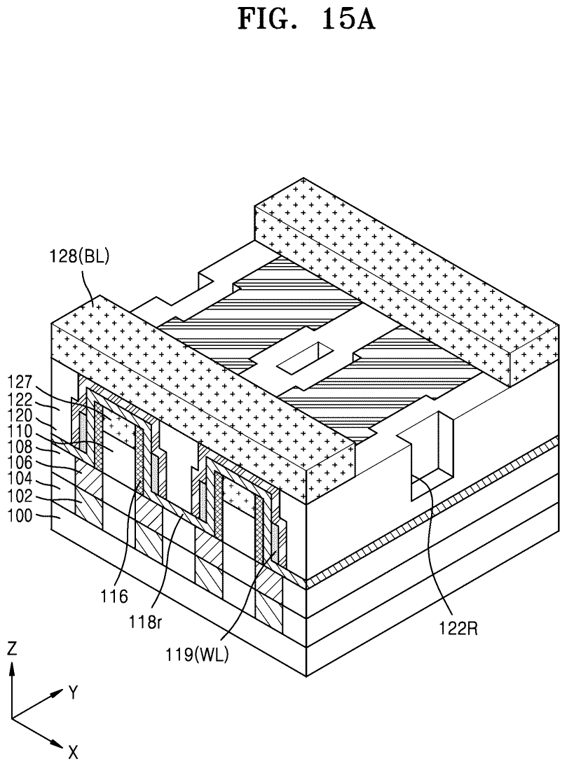

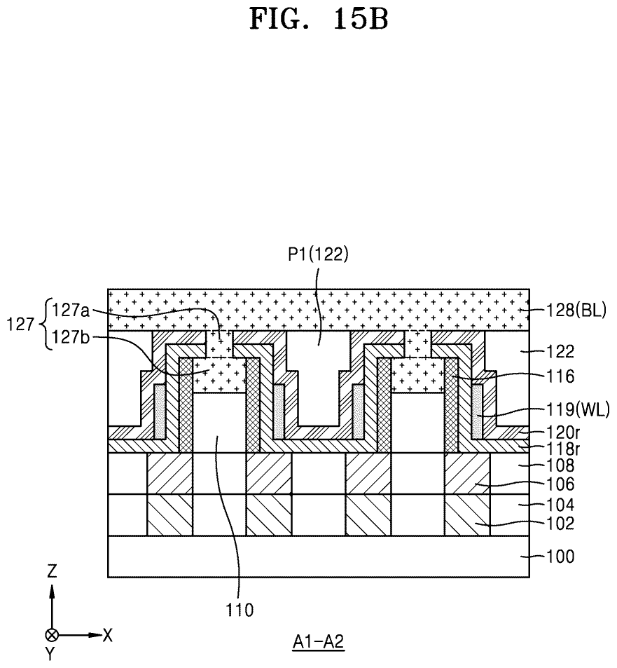

Referring to FIGS. 15A and 15B, the bit line contact plug 127 is formed inside the first contact hole (124 of FIGS. 14A and 14B) and the second contact hole (126 of FIGS. 14A and 14B). The bit line contact plug 127 includes the first bit line contact plug 127a and the second bit line contact plug 127b. The first bit line contact plug 127a may be formed inside the first contact hole (124 in FIGS. 14A and 14B). The second bit line contact plug 127b may be formed inside the second contact hole (126 in FIGS. 14A and 14B).

Subsequently, the plurality of bit lines 128 are formed. The plurality of bit lines 128 may be formed as a conductive pattern. The plurality of bit lines 128 may include the same material as that of the bit line contact plug 127. The plurality of bit lines 128 and the bit line contact plug 127 may be formed as the same body.

The bit line contact plug 127 and the plurality of bit lines 128 may be formed in a single metal deposition process. The bit line contact plug 127 and the plurality of bit lines 128 may include the same material.

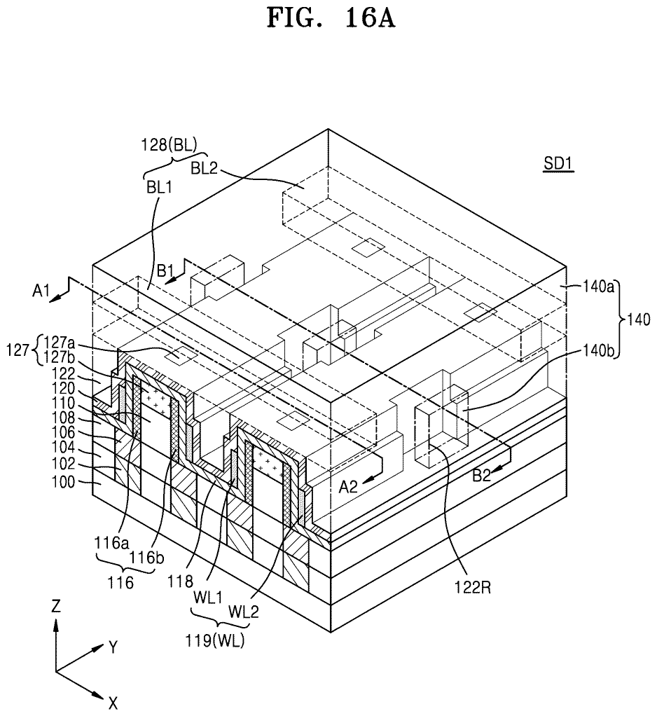

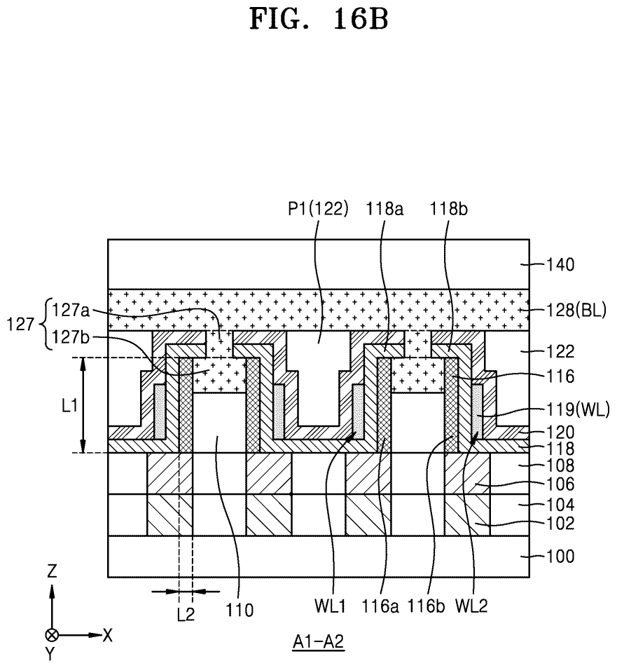

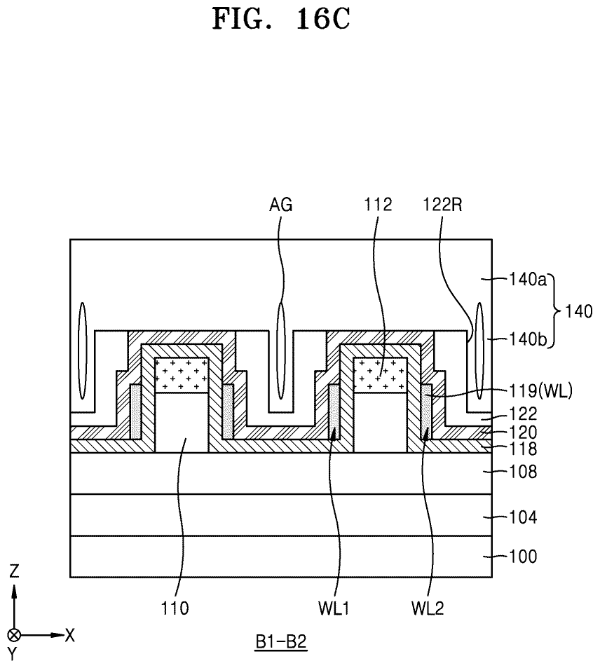

Referring to FIGS. 16A, 16B, and 16C, the second mold insulating layer 140 covering the opposite sidewalls and upper surfaces of the plurality of bit lines 128 and the upper surface of the first mold insulating layer 122 and extending into the recess 122R is formed. The second mold insulating layer 140 may include the main extension 140a covering both sidewalls and the upper surfaces of the plurality of bit lines 128 and the upper surface of the first mold insulating layer 122 and the sub-extension 140b extending from the main extension 140a to the recess 122R.

When the second mold insulating layer 140 is formed inside the recess 122R, the air gap AG may be formed because the second mold insulating layer 140 does not completely fill the inside of the recess 122R. The second mold insulating layer 140 may include a material having relatively high step coverage.

Subsequently, after removing the substrate 100, the result after the substrate (100) has been removed may be bonded with the peripheral circuit structure (PS of FIG. 2) described above.

Because the air gaps AG are placed between the plurality of word lines 119 and between the plurality of bit lines 128, parasitic capacitance may be reduced. Accordingly, the semiconductor device of the inventive concept may improve electrical characteristics by reducing signal delay.

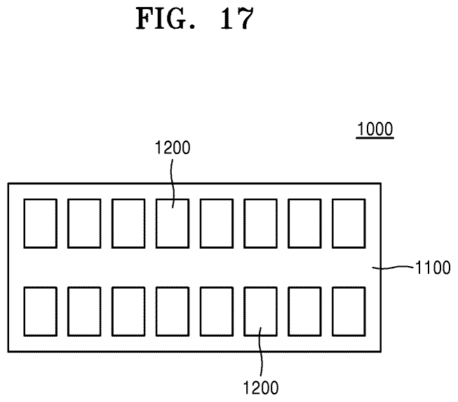

FIG. 17 is a plan view of a memory module 1000 including a semiconductor device according to the inventive concept.

For example, the memory module 1000 may include a printed circuit board 1100 and a plurality of semiconductor packages 1200. The plurality of semiconductor packages 1200 may include semiconductor devices according to embodiments of the inventive concept.

The memory module 1000 may be a single in-lined memory module (SIMM) in which the plurality of semiconductor packages 1200 are mounted on only one side of a printed circuit board or a dual in-lined memory module (DIMM) in which the plurality of semiconductor packages 1200 are arranged on opposite sides of a printed circuit board. In addition, the memory module 1000 may be a fully buffered DIMM (FBDIMM) having an advanced memory buffer (AMB) that provides external signals to the plurality of semiconductor packages 1200, respectively.

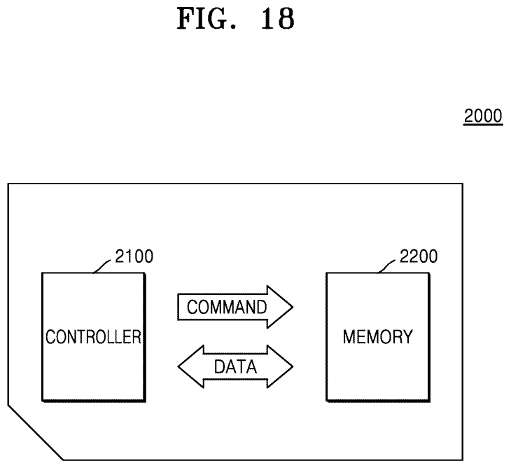

FIG. 18 is a schematic diagram of a memory card 2000 including a semiconductor device according to the inventive concept.

As an example, the memory card 2000 may be arranged so that a controller 2100 exchanges electrical signals with a memory 2200. For example, when the controller 2100 issues a command, the memory 2200 may transmit data.

The controller 2100 may include a semiconductor device of the inventive concept. The memory 2200 may include a semiconductor device of the inventive concept. The memory card 2000 may include various types of memory cards, such as a memory stick card, a smart media (SM) card, a secure digital (SD) card, a mini-secure digital (mini SD) card, and a multimedia card (MMC).

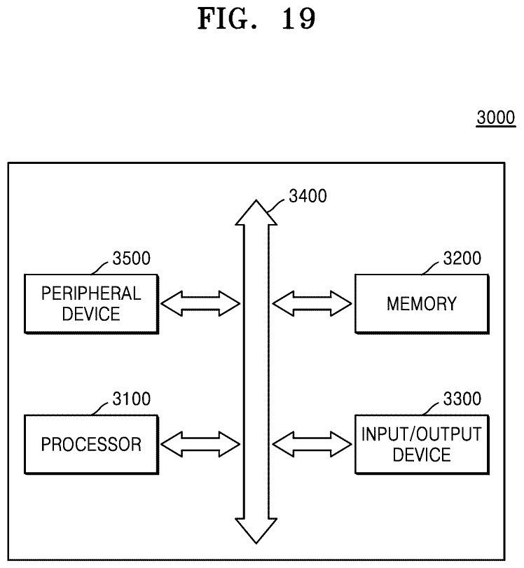

FIG. 19 is a schematic diagram of a system 3000 including a semiconductor device according to the inventive concept.

As an example, in the system 3000, a processor 3100, a memory 3200, and an input/output device 3300 may exchange data with each other using a bus 3400. The memory 3200 of the system 3000 may include random access memory (RAM) and read-only memory (ROM). In addition, the system 3000 may include a peripheral device 3500, such as a floppy disk drive and a compact disk (CD) ROM drive.

The memory 3200 may include a semiconductor device of the inventive concept. The memory 3200 may store code and data for the operation of the processor 3100. The system 3000 may be used in a mobile phone, an MP3 player, a navigation device, a portable multimedia player (PMP), a solid state disk (SSD), or household appliances.

While the inventive concept has been particularly shown and described with reference to embodiments thereof, it will be understood that various changes in form and details may be made therein without departing from the spirit and scope of the following claims.

What is claimed is:

1. A semiconductor device comprising:
a first word line and a second word line spaced apart from each other in a first horizontal direction and extending in a second horizontal direction intersecting the first horizontal direction;
a gate insulating layer disposed on inner sidewalls of the first word line and the second word line;
a first channel layer and a second channel layer respectively spaced apart from the inner sidewalls of the first word line and the second word line with the gate insulating layer therebetween;
a channel isolation insulating layer disposed between the first channel layer and the second channel layer;
a bit line contact plug disposed on the channel isolation insulating layer and electrically connected to the first channel layer and the second channel layer;
a bit line disposed on the bit line contact plug, electrically connected to the bit line contact plug, and extending in the first horizontal direction;
a first mold insulating layer facing an outer sidewall of each of the first word line and the second word line and extending in the second horizontal direction along the outer sidewall of each of the first word line and the second word line; and
a second mold insulating layer disposed on the first mold insulating layer and covering opposite sidewalls and an upper surface of the bit line,
wherein the first mold insulating layer includes a recess, and
the second mold insulating layer includes a portion extending into the recess of the first mold insulating layer.

2. The semiconductor device of claim 1, wherein the first mold insulating layer comprises:
a first portion overlapping the first channel layer and the second channel layer in the first horizontal direction; and
a second portion not overlapping the first channel layer and the second channel layer in the first horizontal direction,
wherein a second width of the second portion in the first horizontal direction is greater than a first width of the first portion in the first horizontal direction.

3. The semiconductor device of claim 2, wherein the recess of the first mold insulating layer is disposed in the second portion of the first mold insulating layer.

4. The semiconductor device of claim 1, wherein the second mold insulating layer comprises:
a main extension covering the opposite sidewalls and the upper surface of the bit line; and
a sub-extension extending from the main extension into the recess,
wherein the sub-extension includes an air gap.

5. The semiconductor device of claim 4, wherein the sub-extension of the second mold insulating layer does not overlap the first channel layer and the second channel layer in the first horizontal direction.

6. The semiconductor device of claim 1, wherein vertical levels of upper surfaces of the first channel layer and the second channel layer are higher than vertical levels of upper surfaces of the first word line and the second word line.

7. The semiconductor device of claim 1, wherein the gate insulating layer covers outer sidewalls and upper surfaces of the first channel layer and the second channel layer and a portion of an upper surface of the bit line contact plug.

8. The semiconductor device of claim 1, further comprising a capping insulating layer covering outer sidewalls and upper surfaces of the first word line and the second word line, a portion of an outer sidewall of the gate insulating layer not covered by the first word line and the second word line, and an upper surface of the gate insulating layer.

9. The semiconductor device of claim 8, wherein the recess of the first mold insulating layer exposes the capping insulating layer from a bottom surface of the recess and exposes the first mold insulating layer from a side surface of the recess.

10. The semiconductor device of claim 8, wherein the recess of the first mold insulating layer exposes the first mold insulating layer from a bottom surface and a side surface of the recess, and
the capping insulating layer is spaced apart from the bottom surface and the side surface of the recess.

11. A semiconductor device comprising:
a first word line and a second word line spaced apart from each other in a first horizontal direction and extending in a second horizontal direction intersecting the first horizontal direction;
a gate insulating layer disposed on inner sidewalls of the first word line and the second word line;
a first channel layer and a second channel layer respectively spaced apart from the inner sidewalls of the first word line and the second word line with the gate insulating layer therebetween;
a channel isolation insulating layer disposed between the first channel layer and the second channel layer;
a bit line contact plug disposed on the channel isolation insulating layer and electrically connected to the first channel layer and the second channel layer;
a bit line disposed on the bit line contact plug, electrically connected to the bit line contact plug, and extending in the first horizontal direction;
a capping insulating layer covering outer sidewalls and upper surfaces of the first word line and the second word line and a portion of an outer sidewall and an upper surface of the gate insulating layer; and
a mold insulating layer covering opposite sidewalls and an upper surface of the bit line and facing the outer sidewall of each of the first word line and the second word line,
wherein the mold insulating layer includes an air gap disposed in a position not overlapping the bit line in a vertical direction and not overlapping the first channel layer and the second channel layer in the first horizontal direction.

12. The semiconductor device of claim 11, wherein the mold insulating layer includes a first mold insulating layer and a second mold insulating layer on the first mold insulating layer,
the first mold insulating layer includes a recess, and
the second mold insulating layer includes:
a main extension covering the opposite sidewalls and the upper surface of the bit line; and
a sub-extension extending from the main extension into the recess.

13. The semiconductor device of claim 12, wherein the air gap is located in the sub-extension of the second mold insulating layer.

14. The semiconductor device of claim 11, wherein the mold insulating layer comprises:
a first portion overlapping the first channel layer and the second channel layer in the first horizontal direction; and
a second portion not overlapping the first channel layer and the second channel layer in the first horizontal direction,
wherein a second width of the second portion in the first horizontal direction is greater than a first width of the first portion in the first horizontal direction.

15. The semiconductor device of claim 14, wherein the air gap overlaps the second portion of the mold insulating layer in the first horizontal direction.

16. The semiconductor device of claim 11, wherein the first channel layer and the second channel layer include a semiconductor pattern including an oxide semiconductor, and
the first channel layer and the second channel layer include a first contact portion in contact with the bit line contact plug and a second contact portion in contact with the channel isolation insulating layer.

17. The semiconductor device of claim 11, wherein the bit line contact plug comprises:
a first bit line contact plug disposed in a first contact hole penetrating the capping insulating layer and the gate insulating layer; and
a second bit line contact plug disposed in a second contact hole in contact with both the first channel layer and the second channel layer.

18. A semiconductor device comprising:
a first word line and a second word line spaced apart from each other in a first horizontal direction and extending in a second horizontal direction intersecting the first horizontal direction;
a gate insulating layer disposed on inner sidewalls of the first word line and the second word line;
a first channel layer and a second channel layer respectively spaced apart from the inner sidewalls of the first word line and the second word line with the gate insulating layer therebetween;
a channel isolation insulating layer located between the first channel layer and the second channel layer;
a bit line contact plug disposed on the channel isolation insulating layer and electrically connected to the first channel layer and the second channel layer;
a bit line disposed on the bit line contact plug, electrically connected to the bit line contact plug, and extending in the first horizontal direction;
a capping insulating layer covering outer sidewalls and upper surfaces of the first word line and the second word line and a portion of an outer sidewall and an upper surface of the gate insulating layer;
a first mold insulating layer extending in the second horizontal direction on the capping insulating layer; and
a second mold insulating layer disposed on the first mold insulating layer and covering opposite sidewalls and an upper surface of the bit line,
wherein the first mold insulating layer includes a recess, and
the recess is disposed in a position not overlapping the bit line in a vertical direction and not overlapping the first channel layer and the second channel layer in the first horizontal direction.

19. The semiconductor device of claim 18, wherein the second mold insulating layer comprises:
a main extension covering the opposite sidewalls and the upper surface of the bit line; and
a sub-extension extending from the main extension into the recess,
wherein the sub-extension includes an air gap.

20. The semiconductor device of claim 18, wherein the bit line contact plug comprises:
a first bit line contact plug disposed in a first contact hole penetrating the capping insulating layer and the gate insulating layer; and
a second bit line contact plug disposed in a second contact hole in contact with both the first channel layer and the second channel layer.
